(19) United States
(12) Patent Application Publication
(10) Pub. No.: US 2021/0367016 A1
(43) Pub. Date: Nov. 25, 2021

(54) THIN FILM TRANSISTOR, ARRAY SUBSTRATE AND DISPLAY PANEL THEREOF

(71) Applicant: WUHAN CHINA STAR OPTOELECTRONICS SEMICONDUCTOR DISPLAY TECHNOLOGY CO., LTD., Wuhan, Hubei (CN)

(72) Inventor: Fang QIN, Wuhan, Hubei (CN)

(21) Appl. No.: 16/489,405

(22) PCT Filed: Apr. 18, 2019
(86) PCT No.: PCT/CN2019/083134

§ 371 Date: Aug. 28, 2019

(30) Foreign Application Priority Data
Feb. 28, 2019 (CN) 201910153027.7

(51) Int. Cl. H01L 27/32

(52) U.S. Cl. CPC H01L 27/3258; H01L 27/1222; H01L 27/3262

(57) ABSTRACT

The present invention relates to a thin film transistor, an array substrate and a display panel thereof. The present invention obtains SiNx layers with different densities and hydrogen contents by adjusting a SiNx film forming process of an interlayered insulating layer in a thin film transistor. The second layer having a lower density has a higher hydrogen content, but has a poor hydrogen barrier capability, while the first layer having a higher density has less hydrogen content, but has a better hydrogen barrier capability. Through a combination of SiNx layers having different densities, the hydrogen replenishment capability can be differentiated, thereby achieving different degrees of adjustment of electrical properties of the low-temperature polysilicon thin film transistor, simplifying the channel doping process, thus reducing the production cost.

### BACKGROUND OF INVENTION

### Field of Invention

The present invention relates to a field of display technologies, and in particular, to a thin film transistor, an array substrate and a display panel thereof.

### Description of Prior Art

With the progression of the times, there are many types of display technologies, including liquid crystal displays (LCDs) and organic light-emitting diode displays (OLEDs). The OLED display devices are also referred to as organic electric laser display devices and organic light emitting semiconductors. A basic structure of the OLED is a structure sandwiched between a thin and transparent indium tin oxide (ITO) having semiconductor characteristics and electrically connected to a positive electrode, and a metal surface cathode. The entire structure includes a hole transport layer (HTL), a light-emitting layer (EL), and an electron transport layer (ETL). When the power supply reaches an appropriate voltage, holes from the positive electrode and electron from the cathode are combined in the light-emitting layer, and form the excitons (electron-hole pairs) in an excited state at a certain probability under an action of Coulomb force. The excited state is unstable in normal environment, and the excitons in the excited state are recombined and transfer energy to the luminescent material, resulting in a transition of the luminescent material from a ground state level to an excited state. Energy in the excited state generates photons through a radiation relaxation process, releasing light for illumination, and generates red, green, or blue primary colors according to different formulas to form basic colors.

First of all, the characteristics of the OLEDs include self-illumination, and no backlight is required, so the visibility and brightness are high. Secondly, the OLEDs have become one of the most important display technologies today due to their advantages of low voltage demand, high power saving efficiency, fast response times, light weights, thin thicknesses, simple structures, low costs, wide viewing angles, almost infinite contrast, low power consumption, and high reaction rates, gradually replacing TFT-LCDs and expected to become the mainstream display technology of next generation after LCD.

A conventional OLED flexible display panel includes a flexible substrate and a pixel circuit layer, an anode, an organic light-emitting layer, a cathode, a thin film encapsulation layer, and the like formed on the flexible substrate. The pixel circuit layer includes a thin film transistor unit (TFT), a line (scanning line or data line, etc.) connected to the thin film transistor unit, and the thin film transistor unit includes stacked conductive layers such as a semiconductor layer, a gate, a source, and a drain etc., and insulating layers provided between the conductive layers.

With development of high-resolution products, array thin film transistors are required to have smaller size, and the thin film transistors of low-temperature polysilicon have become the top choice technology for products of high-resolution and small to medium-size due to their high carrier mobility. Since there are many defects, such as broken bonds and weak bonds, at an interface between polysilicon grains, at an interface between the polysilicon and the gate insulating layer, and in the gate insulating layer, in the manufacturing process of the low temperature polysilicon thin film transistor, an annealing process is required for hydrogen replenishment. A high-temperature annealing process in combination with hydrogen activation is generally employed, wherein the hydrogen source is a SiNx film to achieve the effect of repairing these defects, thereby optimizing electrical characteristics of the thin film transistor, such as threshold voltage (Vth), sub-threshold swing (SS), etc. However, in the current process, when the SiNx film is used as a hydrogen source, degree of the hydrogen replenishment of the thin film transistor is difficult to control. Therefore, it is usually necessary to introduce a channel doping process for an auxiliary adjustment, thereby achieving the required electrical characteristics, resulting in a more complicated process and an increased cost. Therefore, there is a need to find a new thin film transistor to solve the above problems.

### SUMMARY OF INVENTION

An object of the present invention is to provide a thin film transistor which can solve the problem that the degree of hydrogen replenishment of the conventional thin film transistor is difficult to control.

In order to solve the above problems, an embodiment of the present invention provides a thin film transistor including: a substrate, a buffer layer, a polysilicon layer, a gate insulating layer, a gate, an interlayered insulating layer, a source, and a drain. The buffer layer is disposed on the substrate; the polysilicon layer is disposed on the buffer layer; the gate insulating layer is disposed on the buffer layer and the polysilicon layer; the gate is disposed on the gate insulating layer; the interlayered insulating layer is disposed on the gate insulating layer and the gate; the source is disposed on the polysilicon layer; and the drain is disposed on the polysilicon layer. The interlayered insulating layer includes a SiNx layer. The SiNx layer includes a first layer and a second layer; the first layer is made of SiNx having a first density; and the second layer is made of SiNx having a second density.

Further, the first density is greater than the second density.

Further, an etching rate of the first layer at 1% hydrofluoric acid is less than 13 Å/s due to the first density.

Further, an etching rate of the second layer at 1% hydrofluoric acid is greater than or equal to 13 Å/s due to the second density.

Further, the second layer is disposed on the first layer, and the first layer is disposed between the gate insulating layer and the second layer.

Further, the first layer is disposed on the second layer, and the second layer is disposed between the gate insulating layer and the first layer.

Further, the first layer has a thickness greater than 150 angstroms.

Another embodiment of the present invention further provides an array substrate, provided with the thin film transistor according to the present invention.

Another embodiment of the present invention also provides a display panel including the array substrate according to the present invention.

Further, a planar layer, a pixel defining layer, and a light emitting layer are sequentially disposed on the array substrate.

The present invention relates to a thin film transistor, an array substrate and a display panel thereof. The present invention obtains SiNx layers with different densities and hydrogen contents by adjusting a SiNx film forming process of an interlayered insulating layer in a thin film transistor. The second layer having a lower density has a higher hydrogen content, but has a poor hydrogen barrier capability, while the first layer having a higher density has less hydrogen content, but has a better hydrogen barrier capability. Through a combination of SiNx layers having different densities, the hydrogen replenishment capability can be differentiated, thereby achieving different degrees of adjustment of electrical properties of the low-temperature polysilicon thin film transistor, simplying the channel doping process, thus reducing the production cost.

### BRIEF DESCRIPTION OF DRAWINGS

In order to more clearly illustrate the embodiments or the technical solutions of the existing art, the drawings illustrating the embodiments or the existing art will be briefly described below. Obviously, the drawings in the following description merely illustrate some embodiments of the present invention. Other drawings may also be obtained by those skilled in the art according to these figures without paying creative work.

FIG. 1 is a schematic structural view of a thin film transistor according to an embodiment of the present invention.

FIG. 2 is a schematic structural view of a SiNx layer of an interlayered insulating layer in the thin film transistor shown in FIG. 1 according to an embodiment of the present invention.

FIG. 3 is a schematic structural view of a SiNx layer of an interlayered insulating layer in the thin film transistor shown in FIG. 1 according to another embodiment of the present invention.

Elements in the drawings are designated by reference numerals listed below.
100, thin film transistor
1, the substrate
2, buffer layer
3, polysilicon layer
4, gate insulating layer
5, gate
6, interlayered insulating layer
7, source
8, drain
61, first layer
62, second layer

### DETAILED DESCRIPTION OF PREFERRED EMBODIMENTS

Please refer to the figures in the drawings, in which, like numbers refer to like elements throughout the description of the figures. Hereinafter, the present invention will be described in further detail with reference to examples. It is to be understood, however, that these examples are for illustrative purposes only and are not intended to limit the scope of the present invention.

The following description of the various embodiments is provided to illustrate the specific embodiments of the invention. The spatially relative directional terms mentioned in the present invention, such as “upper”, “lower”, “before”, “after”, “left”, “right”, “inside”, “outside”, “side”, etc. and the like, may be used herein for ease of description to describe one element or feature's relationship to another element(s) or feature(s) as illustrated in the figures which are merely references. The spatially relative terms are intended to encompass different orientations in addition to the orientation as depicted in the figures.

In the drawings, structurally identical components are denoted by the same reference numerals, and structural or functionally similar components are denoted by like reference numerals. Moreover, the size and thickness of each component shown in the drawings are arbitrarily shown for ease of understanding and description, and the present invention does not limit the size and thickness of each component.

When a component is described as “on” another component, the component can be placed directly on the other component; there can also be an intermediate component that is placed on the intermediate component, and the intermediate component is placed on another component. When a component is described as “installed to” or “connected to” another component, it can be understood as that a component directly “installed to” or “connected to” another component, or a component is “mounted to” or “connected” to another component through an intermediate component.

### Embodiment 1

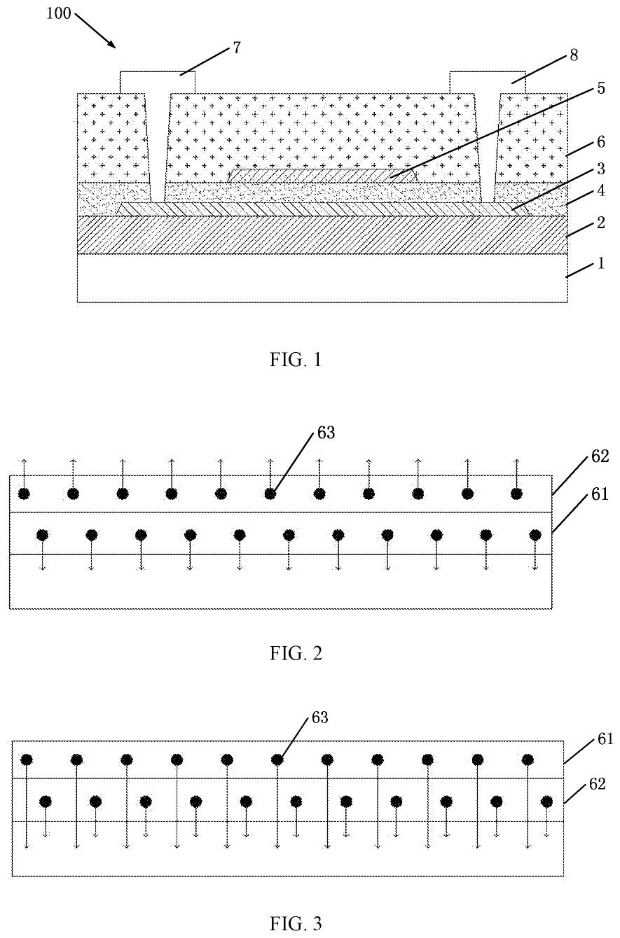

As shown in FIG. 1, a thin film transistor 100 of this embodiment includes a substrate 1, a buffer layer 2, a polysilicon layer 3, a gate insulating layer 4, a gate 5, an interlayered insulating layer 6, a source 7, and a drain 8. The buffer layer 2 is disposed on the substrate 1; the polysilicon layer 3 is disposed on the buffer layer 2; the gate insulating layer 4 is disposed on the buffer layer 2 and the polysilicon layer 3; the gate 5 is disposed on the gate insulating layer 4; the interlayered insulating layer 6 is disposed on the gate insulating layer 4 and the gate 5; the source 7 is disposed on the polysilicon layer 3; and the drain 8 is disposed on the polysilicon layer 3.

As shown in FIG. 2, the interlayered insulating layer 6 includes a SiNx layer, and in other embodiments, it may also include a SiNx layer and an SiOx layer, but is not limited thereto. The SiNx layer includes a first layer 61 and a second layer 62, wherein the second layer 62 is disposed on the first layer 61, and the first layer 61 is disposed between the gate insulation layer 4 and the second layer 62. The first layer 61 is made of SiNx having a first density; and the second layer 62 is made of SiNx having a second density. The first density is greater than the second density, wherein specifically, an etching rate of the first layer 61 at 1% hydrofluoric acid is less than 13 Å/s due to the first density, and an etching rate of the second layer 62 at 1% hydrofluoric acid is greater than or equal to 13 Å/s due to the second density. The second layer having a lower density has a higher hydrogen content, but has a poor hydrogen barrier capability, while the first layer having a higher density has less hydrogen content, but has a better hydrogen barrier capability, such that H+63 inside the second layer 62 are prevented from penetrating the first layer 61, thereby satisfying the need to reduce the amount of hydrogen replenishment, achieving different degrees of adjustment of electrical properties of the low-temperature polysilicon thin film transistor, simplifying the channel doping process, and thus reducing the production cost.

As shown in FIG. 2, the first layer 61 has a thickness greater than 150 angstroms, and thereby, the effect of blocking the penetration of the H+63 in the second layer 62 can be achieved.

### Embodiment 2

Only the differences between the present embodiment and the embodiment 1 will be described below, and the same contents will not be repeated herein for brevity.

As shown in FIG. 3, the interlayered insulating layer 6 includes a SiNx layer, and in other embodiments, it may also include a SiNx layer and an SiOx layer, but is not limited thereto. The SiNx layer includes a first layer 61 and a second layer 62, wherein the first layer 61 is disposed on the second layer 62, and the second layer 62 is disposed between the gate insulation layer 4 and the first layer 61. The first layer 61 is made of SiNx having a first density; and the second layer 62 is made of SiNx having a second density. The first density is greater than the second density, wherein specifically, an etching rate of the first layer 61 at 1% hydrofluoric acid is less than 13 Å/s due to the first density, and an etching rate of the second layer 62 at 1% hydrofluoric acid is greater than or equal to 13 Å/s due to the second density. The second layer having a lower density has a higher hydrogen content, but has a poor hydrogen barrier capability, while the first layer having a higher density has less hydrogen content, but has a better hydrogen barrier capability, such that H+ 63 inside the first layer 61 and the second layer 62 are all transmitted downward, thereby satisfying the need to reduce the amount of hydrogen replenishment, achieving different degrees of adjustment of electrical properties of the low-temperature polysilicon thin film transistor, simplifying the channel doping process, and thus reducing the production cost.

The present invention also provides an array substrate, wherein the thin film transistor 100 of the present invention is provided on the array substrate.

The present invention also provides a display panel including the array substrate according to the present invention. Further, a planarization layer, a pixel defining layer, and a light emitting layer are sequentially disposed on the array substrate.

The thin film transistor, the array substrate and the display panel thereof provided by the present invention are described in detail above.

It is understood that the exemplary embodiments described herein are to be considered as illustrative only, and are not intended to limit the present invention. Descriptions of features or aspects in each exemplary embodiment should generally be considered as suitable features or aspects in other exemplary embodiments. While the present invention has been described with reference to the preferred embodiments thereof, various modifications and changes can be made by those skilled in the art. The present invention is intended to cover such modifications and variations within the scope of the appended claims, and any modifications, equivalents, and modifications within the spirit and scope of the present invention are intended to be included within the scope of the present invention.

What is claimed is:

1. A thin film transistor, comprising:
a substrate
a buffer layer disposed on the substrate;
a polysilicon layer disposed on the buffer layer;
a gate insulating layer disposed on the buffer layer and the polysilicon layer;
a gate disposed on the gate insulating layer;
an interlayered insulating layer disposed on the gate insulating layer and the gate;
a source disposed on the polysilicon layer; and
a drain disposed on the polysilicon layer,
wherein the interlayered insulating layer comprises a SiNx layer, and the SiNx layer comprises:
a first layer made of SiNx having a first density; and
a second layer made of SiNx having a second density.

2. The thin film transistor of claim 1, wherein the first density is greater than the second density.

3. The thin film transistor of claim 1, wherein an etching rate of the first layer at 1% hydrofluoric acid is less than 13 Å/s due to the first density.

4. The thin film transistor of claim 1, wherein an etching rate of the second layer at 1% hydrofluoric acid is greater than or equal to 13 Å/s due to the second density.

5. The thin film transistor of claim 1, wherein the second layer is disposed on the first layer, and the first layer is disposed between the gate insulating layer and the second layer.

6. The thin film transistor of claim 1, wherein the first layer is disposed on the second layer, and the second layer is disposed between the gate insulating layer and the first layer.

7. The thin film transistor of claim 1, wherein the first layer has a thickness greater than 150 angstroms.

8. An array substrate, comprising the thin film transistor of claim 1 disposed on the array substrate.

9. A display panel comprising the array substrate of claim 8.

10. The display panel according to claim 9, wherein a planarization layer, a pixel defining layer, and a light emitting layer are further disposed sequentially on the array substrate.
